(19) United States
(12) Patent Application Publication
(10) Pub. No.: US 2017/0010605 A1
(43) Pub. Date: Jan. 12, 2017

(54) Method and System for Providing an Improved Wafer Transport System

(71) Applicant: Macronix International Co., Ltd., Hsin-chu (TW)

(72) Inventor: Yu Chen Chuang, Hsinchu City (TW)

(21) Appl. No.: 14/796,428

(22) Filed: Jul. 10, 2015

(51) Int. Cl. G05B 19/418; H01L 21/67; H01L 21/677

(52) U.S. Cl. CPC G05B 19/4189; H01L 21/6773; H01L 21/67276; G05B 2219/45031

(57) ABSTRACT

A method of controlling a delivery to a working station comprises processing first carrier of wafers at a working station for a processing step, checking location of a second carrier at a predetermined checking time to obtain a checking result. The predetermined checking time is a predetermined period of time ahead of an end of the processing step. The method further comprises removing the first carrier from the working station after the processing step is completed, delivering a second carrier of wafers to the working station and processing the second carrier of wafers at the working station.

### TECHNOLOGICAL FIELD

The present invention generally relates to wafer processing systems. More specifically, the invention relates to wafer transport systems.

### BACKGROUND

In manufacturing of a product, the product may be processed at many processing machines. Semiconductor manufacturing, in particular, may require hundreds of processing steps involving more than a hundred different process tools. A semiconductor wafer may be transported between various processing tools in order to facilitate various fabrication processes. For instance, to complete the fabrication of an integrated circuit chip, the integrated circuit chip may be subjected to deposition, cleaning, ion implantation, etching, and passivation processes before the integrated circuit chip is packaged for shipment. Each of these fabrication steps may be performed in a different process machine (e.g., a chemical vapor deposition chamber, an ion implantation chamber, an etcher). A partially processed semiconductor wafer may be transported between various processing tools before the fabrication process is completed. Therefore, the transportation of semiconductor wafers between processing tools and stockers may be essential in the manufacturing process.

Transportation between processing tools and stockers may be provided by handling systems (e.g., automated material handling systems (AMHS)) capable of transporting wafer carriers to desired processing tools. As economics plays an increasing role in the semiconductor manufacturing industry, throughput may become the key factor for the viability of future business. It is desirable to achieve high levels of productivity, high levels of performance, and on-time delivery in semiconductor manufacturing.

### BRIEF SUMMARY OF EXEMPLARY EMBODIMENTS OF THE INVENTION

The present invention provides methods and processes for improving productivity of a semiconductor manufacturing process. For example, embodiments of the present invention provide a method and apparatus that improve throughput of transporting wafers to various processing tools.

Embodiments include a method of controlling a delivery to a working station. The method includes processing a first carrier of wafers at a working station for a processing step of a semiconductor manufacturing process, and checking a location of a second carrier at a predetermined checking time to obtain a checking result comprising the location of the second carrier. The predetermined checking time is a predetermined period of time prior to an end of the processing step. The method also includes determining whether to move the second carrier to a stocker within a defined distance of the working station based at least in part on the checking result, removing the first carrier from the working station after the processing step is completed, and processing the second carrier of wafers at the working station.

The method may also include, in response to determining that the location of the second carrier is not within the defined distance of the working station, transporting the second carrier of wafers to at least one of the working station or a stocker within the defined distance of the working station. The method may include identifying the second carrier according to a carrier identifier and determining a current stocker in which the second carrier is located. In some embodiments, the method may include, in response to determining that the location of the second carrier is within the defined distance of the working station, leaving the second carrier in the current stocker. The method may also include loading the second carrier on the working station. The method may include indicating availability of the working station.

Embodiments also include a device for controlling a delivery to a working station. The device includes a processor. The processor is configured to process a first carrier of wafers at a working station for a processing step of a semiconductor manufacturing process and check a location of a second carrier at a predetermined checking time to obtain a checking result comprising the location of the second carrier. The predetermined checking time is a predetermined period of time prior to an end of the processing step. The device is also configured to determine whether to move the second carrier to a stocker within a defined distance of the working station based at least in part on the checking result, to remove the first carrier from the working station after the processing step is completed, and to process the second carrier of wafers at the working station. The processor may be further configured to, in response to determining that the location of the second carrier is not within a defined distance of the working station, transport the second carrier of wafers to at least one of the working station or a stocker within the defined distance of the working station. The processor may be further configured to identify the second carrier according to a carrier identifier and determine a current stocker in which the second carrier is located. The processor may be further configured to, in response to determining that the location of the second carrier is within a defined distance of the working station, leave the second carrier in the current stocker. The processor may be further configured to load the second carrier on the working station. The processor may be further configured to indicate an availability of the working station.

Embodiments also include a computer program product comprising a non-transitory computer readable storage medium and computer program instructions stored therein. The computer program instructions include program instructions configured to process a first carrier of wafers at a working station for a processing step of a semiconductor manufacturing process, and to check a location of a second carrier at a predetermined checking time to obtain a checking result comprising the location of the second carrier. The predetermined checking time is a predetermined period of time prior to an end of the processing step. The program instructions are also configured to determine whether to move the second carrier to a stocker within a defined distance of the working station based at least in part on the checking result, to remove the first carrier from the working station after the processing step is completed, and to process the second carrier of wafers at the working station. The program instructions may be further configured to, in response to determining that the location of the second carrier is not within the defined distance of the working station, transport the second carrier of wafers to at least one of the working station or a stocker located within the defined distance of the working station. The program instructions may be further configured to identify the second carrier according to a carrier identifier and determine a current stocker in which the second carrier is located. The program instructions may be further configured to, in response to determining that the location of the second carrier is within the defined distance of the working station, leave the second carrier in the current stocker. The program instructions may be further configured to load the second carrier on the working station. The program instructions may be further configured to indicate an availability of the working station.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 depicts a flow chart illustrating a method of controlling delivery to a working station in accordance with exemplary embodiments of the invention;

FIG. 2 illustrates a time chart of a transport process at a working station in accordance with exemplary embodiments of the invention; and

FIG. 3 shows a schematic block diagram of an exemplary embodiment of the control circuit.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise. Like numbers refer to like elements throughout.

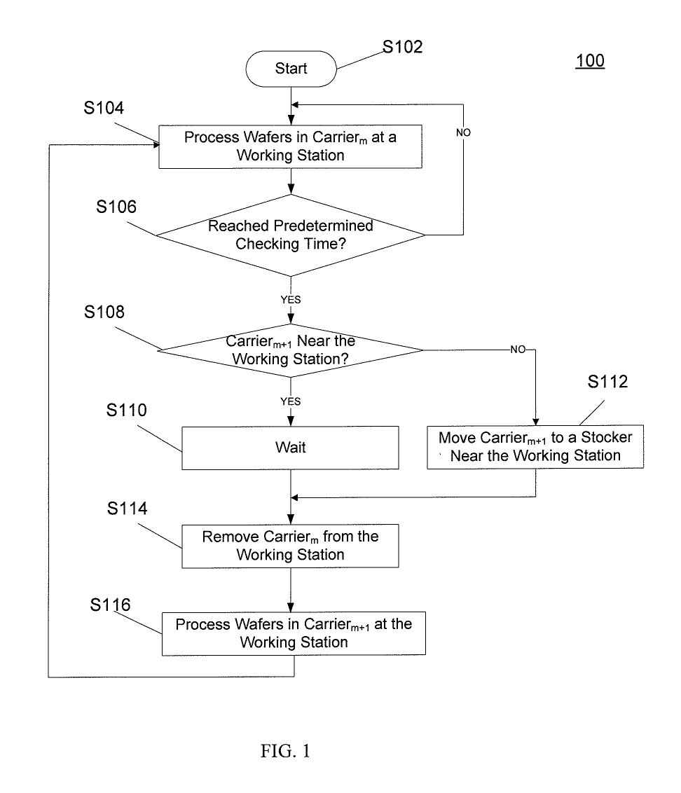

FIG. 1 depicts a flow chart illustrating a method of controlling a carrier delivery to a working station in accordance with exemplary embodiments of the invention. In a semiconductor fab, there may be thousands of carriers, each of which may have tens of wafers. These carriers may be processed through several hundred steps across upward of several hundred different types of working stations include a variety of machines, equipment and/or processing tools. As the process may become more and more complicated, different production methods and procedures may be implemented. A handling system may manage the physical logistics of processing tens of thousands of carriers on hundreds of pieces of working stations. A handling system may comprise a set of components utilized to store and move materials from one place to another in a semiconductor industry. The handling system may comprise a storage system (e.g., stockers), a transport system, and a software system that controls the handling system. Stockers may be utilized to store carriers as well as to act as connection point between transport systems. In transporting wafers to stockers as well as various working stations, the wafers may be held in carriers, such as Front Opening Unified Pods (FOUPs) or Standard Mechanical Interface (SMIF) pods. Carriers may be delivered within an expected time of delivery to a requested destination, such as a stocker or a processing tool. Material movement in the handling system may be accomplished by the transport systems. Part of a semiconductor fabricator's output may often be lost due to processing tools sitting idle while waiting for material to be delivered. Consequently, having fresh wafers available for processing may enhance productivity and efficiency.

Method 100 illustrated in FIG. 1 may start at step S102. At step S102, a carrier of wafers may be delivered to a working station for a processing step (e.g., a lithograph process). The carrier of wafers may be processed at the working station at step S104. For brevity and convenience, the carrier that contains wafers being processed at the working station is defined as current carrier. The step S104 may comprise several sub-steps depending on the processing step being performed. For example, in a lithography process, the processing step may comprise projecting light through a mask. The wafer at the working station may be covered with a photo-active resist. The light transmitted through the mask may cause a chemical reaction in a compound. In subsequent steps, the image may be developed and stabilized. The cured photo-active resist forms a protective mask to protect areas of the wafer surface from subsequent processing steps such as etching or implantation. When the processing step starts, a counter may be set to count. When a time is reached at step S106, the handling system may check and determine location of a carrier that may be subsequently processed at this working station and obtain a checking result at step S108. For brevity and convenience, a carrier that contains wafers to be processed is defined as a subsequent carrier. The time at which location of a subsequent carrier is checked may be defined as a predetermined checking time. The predetermined checking time may vary depending on the processing step being performed. For example, the predetermined checking time of the lithography may be different than that set during the chemical vapor deposition process. Each carrier may be associated with a carrier identifier. The handling system may determine the location of the carrier based on identification of the carrier identifier. The handling system may determine if the subsequent carrier needs to be transported from a remote stocker to a nearby stocker and/or needs to waiting in a queue for the processing step. If the result obtained at step S108 is yes (i.e., the subsequent carrier is stored in a nearby stocker), the transport system may enter into a waiting status, such that the transport system is waiting for a next instruction at step S110 (e.g., delivering to the working station for the processing step). If the result obtained at step S108 is no, the transport system may enter into a transportation status. In the transportation status, the transport system may deliver the subsequent carrier to a nearby stocker and put the subsequent carrier in queues waiting for the processing tool to become available at step S112. If the processing step takes a time interval PT to implement, the predetermined checking time may be a defined period of time Pt ahead of an end of the processing step, such that the checking time is predetermined at PT-Pt. The period of time Pt may be about 10-15 minutes, depending on the processing step. The transport system may deliver the subsequent carrier to a nearby stocker within the predetermined period of time Pt and make the subsequent carrier available to the working station. When the processing of the current carrier of wafers is completed, the transport system may remove the current carrier form the working station at step S114. The processing tool may become ready for the subsequent carrier. The transport system may then deliver the subsequent carrier to the working station and load the carrier on the working station for the processing step at step S116. The method 100 may then proceed back to step S104 and the processing step for processing the subsequent carrier of wafers may start.

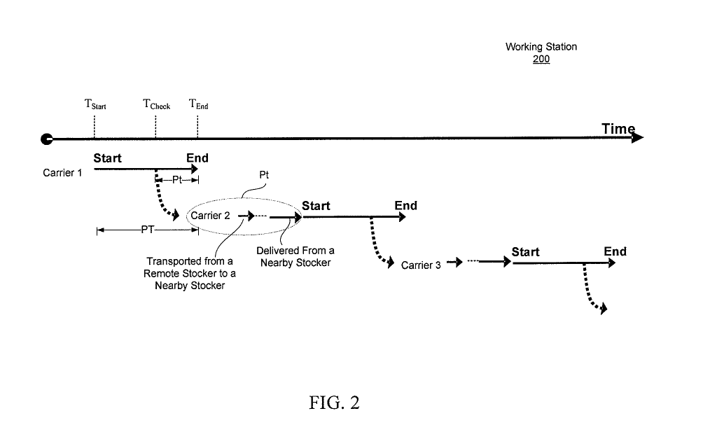

FIG. 2 illustrates a time chart of a transport process at a working station 200 in accordance with example embodiments of the invention. The first carrier may be delivered to the working station for a processing step at a time T_{“start}”. The processing step may be performed over a time interval “PT”. A predetermined checking time may be defined as “T_{check}”. The time T_{Check} may vary according to different processing steps. For example, the time T_{Check} may be a time of period Pt ahead of an end of the processing step T_{END}. When a counter reaches time _{TCheck}, the handling system may identify carrier 2 based on the carrier identifier to determine whether carrier 2 needs to be transported from a remote stocker to a nearby stocker and/or needs to be waiting in the nearby stocker for the processing step. For example, the carrier identifier and or other results of the checking process may determine whether the subsequent carrier is within a defined area about the working station (e.g., in a particular stocker, within a particular radius of the working station, within a particular transit time of the working station, or the like). It should be appreciated that the determination may not be limited just to determining a physical distance between the working station and the subsequent carrier, and other factors than distance may be employed. For example, a transit time (e.g., an amount of time for the subsequent carrier to travel to the working tool) may be employed to determine whether to transport the subsequent carrier to a different stocker. If carrier 2 is not in a nearby stocker, the transport system may deliver carrier 2 from the remote stocker to a nearby stocker within the predetermined period of time Pt. If carrier 2 is in a nearby stocker, carrier 2 will be waiting in the nearby stocker. Once the process step is completed at T_{End}, carrier 1 may be removed from the working station 200. The working station may be available and ready for carrier 2. Carrier 2 may then be delivered to the working station 200 and loaded on the working station 200 for the processing step. The counter may be reset when a new processing step starts. During the processing of wafers in carrier 2, when the counter again reaches the time T_{Check}, the handling system may check the location of carrier 3 and determine if the transport system needs to transport carrier 3 from a remote stocker to a nearby stocker. The handling system may repeatedly perform the steps of checking location of a subsequent carrier at T_{Check} to determine whether the subsequent carrier needs to be transported from a remote stocker to a nearby stocker, transporting the subsequent carrier to a nearby stocker or waiting in a nearby stocker if the subsequent carrier is already nearby, based on the checking result and delivering the subsequent carrier to the working station. In this manner, the subsequent carrier may be delivered to the working station prior to completion of processing of the previous carrier to reduce the time that the processing tool is sitting idle waiting for material to be delivered.

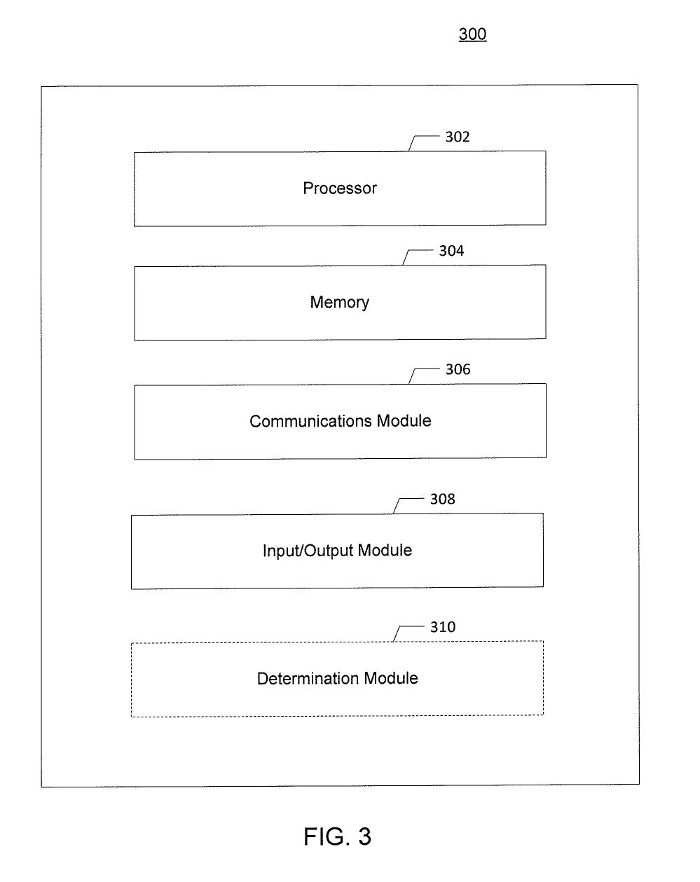

FIG. 3 depicts a schematic block diagram of an exemplary embodiment of the control circuit 300. As illustrated in FIG. 3, in accordance with some example embodiments, the control circuit may include various means, such as processor 302, memory 304, communications module 306, and/or input/output module 308. As referred to herein, “module” includes hardware, software and/or firmware configured to perform one or more particular functions. In this regard, the means of the control circuit as described herein may be embodied as, for example, circuitry, hardware elements (e.g., a suitably programmed processor, combinational logic circuit, and/or the like), a computer program product comprising computer-readable program instructions stored on a non-transitory computer-readable medium (e.g., memory 304) that is executable by a suitably configured processing device (e.g., processor 302), or some combination thereof.

Processor 302 may, for example, be embodied as various means including one or more microprocessors with accompanying digital signal processor(s), one or more processor(s) without an accompanying digital signal processor, one or more microcontroller, one or more coprocessors, one or more multi-core processors, one or more controllers, processing circuitry, one or more computers, various other processing elements including integrated circuits such as, for example, a PLC (program logic controller), an ASIC (application specific integrated circuit) or FPGA (field programmable gate array), or some combination thereof. Accordingly, although illustrated in FIG. 3 as a single processor, in some embodiments processor 302 comprises a plurality of processors. In an example embodiment, processor 302 is configured to execute instructions stored in memory 304 or otherwise accessible to processor 302. These instructions, when executed by processor 302, may cause transport systems to perform one or more of the functionalities illustrated above with respect to FIGS. 1-2.

Whether configured by hardware, firmware/software methods, or by a combination thereof, processor 302 may comprise an entity capable of performing operations according to embodiments of the present invention while configured accordingly. Thus, for example, when processor 302 is embodied as a PLC, ASIC, FPGA or the like, processor 302 may comprise specifically configured hardware for conducting one or more operations described herein. Alternatively, as another example, when processor 302 is embodied as an executor of instructions, such as may be stored in memory 304, the instructions may specifically configure processor 302 to perform one or more algorithms and operations.

Memory 304 may comprise, for example, volatile memory, non-volatile memory, or some combination thereof. Although illustrated in FIG. 3 as a single memory, memory 304 may comprise a plurality of memory components. The plurality of memory components may be embodied on a single computing device or distributed across a plurality of computing devices. In various embodiments, memory 304 may comprise, for example, a hard disk, random access memory, cache memory, flash memory, a compact disc read only memory (CD-ROM), digital versatile disc read only memory (DVD-ROM), an optical disc, circuitry configured to store information, or some combination thereof. Memory 304 may be configured to store information, data (including deal parameter data and/or analytics data), applications, instructions, or the like for enabling valves to carry out various functions in accordance with example embodiments of the present invention. For example, in at least some embodiments, memory 304 is configured to buffer input data for processing by processor 302. Additionally or alternatively, in at least some embodiments, memory 304 is configured to store program instructions for execution by processor 302. Memory 304 may store information in the form of static and/or dynamic information. This stored information may be stored and/or used by the processor 302 during the course of performing its functionalities.

Communications module 306 may be embodied as any device or means embodied in circuitry, hardware, a computer program product comprising computer readable program instructions stored on a computer readable medium (e.g., memory 304) and executed by a processing device (e.g., processor 302), or a combination thereof that is configured to receive and/or transmit data from/to another device, such as, for example, pressure detector, temperature detector, and/or the like. In some embodiments, communications module 306 (like other components discussed herein) can be at least partially embodied as or otherwise controlled by processor 302. In this regard, communications module 306 may be in communication with processor 302, such as via a bus. Communications module 306 may include, network interface card and/or supporting hardware and/or firmware/software for enabling communications with another computing device. Communications module 306 may be configured to receive and/or transmit any data to the processor 302 using any protocol that may be used for communications between computing devices. Communications module 306 may additionally or alternatively be in communication with the memory 304, and/or input/output module 308, such as via a bus.

Input/output module 308 may be in communication with processor 302 to receive signals from detectors, sensors (such as gas flow and radiation), actuators (such as valves and cylinders), switches (such as excess flow switch) and analog process variables (such as temperature and pressure) and to provide an audible, visual, mechanical, or other systems such as valves. The control circuit may include built-in input/output modules or external input/output modules.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A method of controlling a delivery to a working station, comprising:
processing a first carrier of wafers at a working station for a processing step of a semiconductor manufacturing process;
checking a location of a second carrier at a predetermined checking time to obtain a checking result comprising the location of the second carrier, wherein the predetermined checking time is a predetermined period of time prior to an end of the processing step;
determining whether to move the second carrier to a stocker within a defined distance of the working station based at least in part on the checking result;
removing the first carrier from the working station after the processing step is completed; and
processing the second carrier of wafers at the working station.

2. The method of claim 2, further comprising, in response to determining that the location of the second carrier is not within the defined distance of the working station, transporting the second carrier of wafers to at least one of the working station or a stocker within the defined distance of the working station.

3. The method of claim 1, further comprising identifying the second carrier according to a carrier identifier and determining a current stocker in which the second carrier is located.

4. The method of claim 3, further comprising, in response to determining that the location of the second carrier is within the defined distance of the working station, leaving the second carrier in the current stocker.

5. The method of claim 1, further comprising loading the second carrier on the working station.

6. The method of claim 1, further comprising indicating availability of the working station.

7. The method of claim 1, wherein the first carrier is at least one of a Front Opening Unified Pod (FOUP) or a Standard Mechanical Interface (SMIF) pod.

8. A device for controlling a delivery to a working station, comprising a processor configured to:
process a first carrier of wafers at a working station for a processing step of a semiconductor manufacturing process;
check a location of a second carrier at a predetermined checking time to obtain a checking result comprising the location of the second carrier, wherein the predetermined checking time is a predetermined period of time prior to an end of the processing step;
determine whether to move the second carrier to a stocker within a defined distance of the working station based at least in part on the checking result;
remove the first carrier from the working station after the processing step is completed; and
process the second carrier of wafers at the working station.

9. The device of claim 8, wherein the processor is further configured to, in response to determining that the location of the second carrier is not within a defined distance of the working station, transport the second carrier of wafers to at least one of the working station or a stocker within the defined distance of the working station.

10. The device of claim 8, wherein the processor is further configured to identify the second carrier according to a carrier identifier and determine a current stocker in which the second carrier is located.

11. The device of claim 8, wherein the processor is further configured to, in response to determining that the location of the second carrier is within a defined distance of the working station, leave the second carrier in the current stocker.

12. The device of claim 8, wherein the processor is further configured to load the second carrier on the working station.

13. The device of claim 8, wherein the processor is further configured to indicate an availability of the working station.

14. The device of claim 8, wherein the first carrier is at least one of a Front Opening Unified Pod (FOUP) or a Standard Mechanical Interface (SMIF) pod.

15. A computer program product comprising a non-transitory computer readable storage medium and computer program instructions stored therein, the computer program instructions comprising program instructions configured to:
process a first carrier of wafers at a working station for a processing step of a semiconductor manufacturing process;
check a location of a second carrier at a predetermined checking time to obtain a checking result comprising the location of the second carrier, wherein the predetermined checking time is a predetermined period of time prior to an end of the processing step;
determine whether to move the second carrier to a stocker within a defined distance of the working station based at least in part on the checking result;
remove the first carrier from the working station after the processing step is completed; and process the second carrier of wafers at the working station.

16. The computer program product of claim 15, wherein the program instructions are further configured to, in response to determining that the location of the second carrier is not within the defined distance of the working station, transport the second carrier of wafers to at least one of the working station or a stocker located within the defined distance of the working station.

17. The computer program product of claim 15, wherein the program instructions are further configured to identify the second carrier according to a carrier identifier and determine a current stocker in which the second carrier is located.

18. The computer program product of claim 15, wherein the program instructions are further configured to, in response to determining that the location of the second carrier is within the defined distance of the working station, leave the second carrier in the current stocker.

19. The computer program product of claim 15, wherein the program instructions are further configured to load the second carrier on the working station.

20. The computer program product of claim 15, wherein the program instructions are further configured to indicate an availability of the working station.
